(19) United States
(12) Patent Application Publication
(10) Pub. No.: US 2016/0270237 A1
(43) Pub. Date: Sep. 15, 2016

(54) Copper Interconnect Device Including Surface Functionalized Graphene Capping Layer and Fabrication Method Thereof

(71) Applicant: Lam Research Corporation, Fremont, CA (US)

(72) Inventors: Byung Jin Cho, Seoul (KR); Seong Jun Yoon, Seoul (KR); Hyungsuk Alexander Yoon, San Jose, CA (US)

(21) Appl. No.: 15/063,497

(22) Filed: Mar. 7, 2016

(30) Foreign Application Priority Data
Mar. 10, 2015 (KR) 10-2005-0033110

(51) Int. Cl. H05K 3/28; H05K 1/02; H05K 3/10; H05K 3/46; H05K 3/14; H05K 1/09; H05K 1/03

(52) U.S. Cl. CPC H05K 3/28; H05K 1/09; H05K 1/0296; H05K 1/0306; H05K 3/4644; H05K 3/14; H05K 3/10

(57) ABSTRACT

Disclosed is a copper interconnection device including a surface-functionalized graphene capping layer and a method of fabricating the same, wherein electromigration of a fine copper interconnection can be suppressed by the capping layer having a thickness of ones of nm or less. Specifically, graphene is surface-functionalized to possess functional groups able to chemically interact with copper atoms and is thus used as the capping layer, whereby it is difficult to move the copper atoms through the chemical interaction with the functional groups by the use of only the capping layer as thin as ones of nm or less, effectively suppressing electromigration of the copper interconnection.

### CLAIM OF PRIORITY

This application is a Continuation application of Korean Patent Application No. 10-2015-0033110, filed on Mar. 10, 2015, entitled “Copper Interconnect Device Including Surface Functionalized Graphene Capping Layer and Fabrication Method Thereof”, of which is incorporated herein by reference.

### BACKGROUND OF THE INVENTION

1. Field of the Invention

The present invention relates to a copper interconnection device including a surface-functionalized graphene capping layer, and a method of fabricating the same.

2. Description of the Related Art

Copper (Cu), having low electric resistance, is widely utilized as an interconnection material for electronic devices such as semiconductors, displays, etc., instead of conventionally useful aluminum (Al).

Meanwhile, a copper interconnection is problematic because its reliability may deteriorate due to electromigration with a decrease in the line width thereof. Electromigration refers to the migration of metal atoms out of an original crystal structure thereof because the momentum of electrons is transferred to the metal atoms when current flows in a metal interconnection. In the case where electromigration becomes severe, an empty space, that is, a void may be formed in the cathode of the interconnection, thus increasing the resistance of the metal interconnection. In serious cases, open circuits may result, and metal atoms may accumulate on the anode of the interconnection to thus form extrusions, undesirably shorting the interconnection.

Electromigration mainly occurs at the grain boundary or surface of a metal interconnection where metal atoms may be easily moved because of the low activation energy for migration thereof. Since an existing aluminum interconnection includes stable aluminum oxide (Al₂O₃) present on the surface thereof, electromigration mainly occurs at the grain boundary, rather than the surface. In contrast, a copper interconnection is mainly subject to electromigration on the surface thereof, attributable to the absence of a stable surface oxide layer.

With the goal of suppressing electromigration of the copper interconnection, depositing a capping layer made of cobalt (Co) or cobalt tungsten phosphide (CoWP) on the surface of the interconnection is chiefly utilized. However, as the width of the copper interconnection is decreased to tens of nm or less, the thickness of the capping layer is reduced, making it difficult to effectively suppress electromigration of the copper interconnection using the conventional cobalt capping layer. In particular, it is difficult to uniformly form the cobalt capping layer to a thickness as low as ones of nm, and thus considerably non-uniform electromigration may result. Therefore, development of a novel capping layer able to effectively suppress electromigration of a fine interconnection is required.

### SUMMARY OF THE INVENTION

Accordingly, the present invention has been made keeping in mind the above problems encountered in the related art, and an object of the present invention is to provide a copper interconnection device including a capping layer, wherein electromigration may be effectively suppressed on the surface of a copper interconnection even by a capping layer having a thickness of ones of nm or less, and a method of fabricating the same.

In order to accomplish the above object, an aspect of the present invention provides a copper interconnection device, comprising: a copper pattern layer; a liner/barrier layer formed on at least a portion of a lateral surface and a lower surface of the copper pattern layer; a dielectric layer formed so as to come into contact with at least a portion of an outer surface of the liner/barrier layer; and a capping layer formed on an exposed surface of the copper pattern layer, wherein the capping layer is graphene having a functional group on a surface thereof.

The capping layer may be formed on the liner/barrier layer, or may be formed on the dielectric layer.

The capping layer may be a graphene monolayer or multilayer having a functional group on a surface thereof, or may be configured such that surface-functionalized graphene flakes are stacked.

The functional group may be a single functional group or a combination of two or more functional groups.

Another aspect of the present invention provides a method of fabricating a copper interconnection device, comprising: surface-functionalizing graphene; forming a copper interconnection structure; applying the surface-functionalized graphene on the copper interconnection structure; and performing thermal treatment, wherein surface-functionalizing the graphene is forming a functional group on a surface of the graphene.

Surface-functionalizing the graphene may comprise forming a functional group on the surface of the graphene using at least one of inducing a chemical reaction on a surface of the graphene using a chemical, adsorbing a polymer on a surface of the graphene, and polymerizing a monomer on a surface of the graphene, and performing plasma treatment on a surface of the graphene.

Applying the surface-functionalized graphene may comprise at least one of spin coating, spray coating or dip coating using a coating solution including the surface-functionalized graphene, and transferring a surface-functionalized graphene layer.

Applying the surface-functionalized graphene may comprise selectively forming graphene on a portion of the copper interconnection structure, which comprises: applying a self-assembly monolayer material on the copper interconnection structure; applying the surface-functionalized graphene; and removing the self-assembly monolayer material.

According to the present invention, the use of surface-functionalized graphene as a capping layer induces a chemical interaction between functional groups on the surface of the graphene capping layer and copper atoms on the surface of a copper interconnection, thereby effectively suppressing electromigration on the surface of the copper interconnection.

### BRIEF DESCRIPTION OF THE DRAWINGS

The above and other objects, features and advantages of the present invention will be more clearly understood from the following detailed description taken in conjunction with the accompanying drawings, in which:

FIGS. 1A to 1C illustrate copper interconnection structures according to an embodiment of the present invention;

FIGS. 2A to 2C illustrate copper interconnection structures according to another embodiment of the present invention;

FIG. 3 is a schematic flowchart illustrating a process of fabricating a copper interconnection device according to the present invention;

FIG. 4 illustrates selective formation of a surface-functionalized graphene capping layer;

FIG. 5 illustrates chemical interaction between functional groups of the capping layer and copper atoms of the copper pattern layer;

FIG. 6 is a graph illustrating the results of measurement of time to failure of the copper interconnection depending on the presence or absence of the surface-functionalized graphene capping layer; and

FIG. 7 is a graph illustrating the results of measurement of time to failure of the copper interconnection under various temperature conditions depending on the presence or absence of the surface-functionalized graphene capping layer.

### DESCRIPTION OF SPECIFIC EMBODIMENTS

Hereinafter, a detailed description will be given of preferred embodiments of the present invention with reference to the appended drawings, but the present invention is not limited by such embodiments. In the description of the embodiments of the present invention, corresponding constituents are referred to using the same names and the same reference numerals. Also, a detailed description of the related known technology that may unnecessarily obscure the gist of the present invention will be omitted.

According to the present invention, a capping layer for a copper interconnection is formed of surface-functionalized graphene, in lieu of a conventional cobalt capping layer. Functional groups are formed on the surface of graphene through surface functionalization so as to chemically interact with the surface of the copper interconnection, thereby effectively suppressing electromigration on the surface of the copper interconnection.

Graphene refers to a two-dimensional hexagonal carbon material, and may be present in the form of oxidized graphene, or graphene oxide at least a portion of which is reduced. Thus, in the present invention, graphene is to be understood by the broader definition including graphene at least a portion of which is oxidized, or graphene oxide at least a portion of which is reduced.

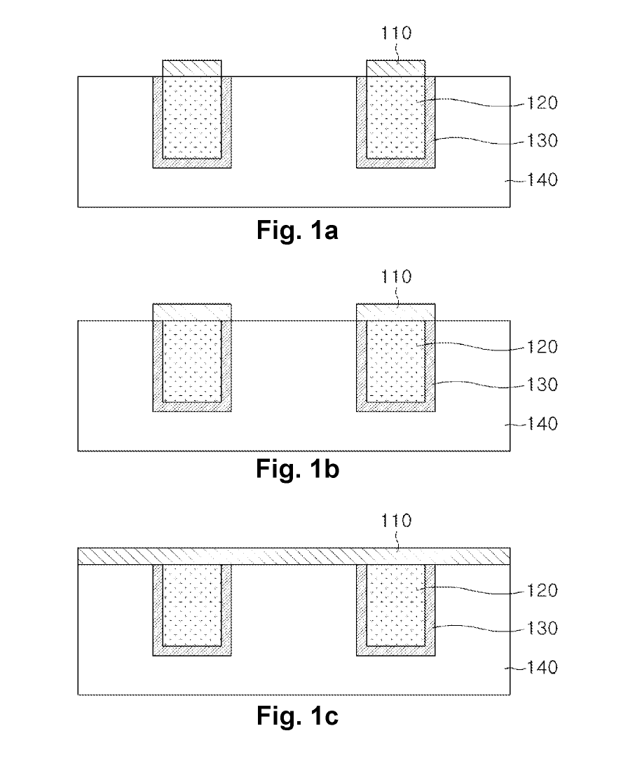

FIGS. 1A to 1C illustrate copper interconnection structures according to an embodiment of the present invention. As illustrated in FIG. 1A, the copper interconnection structure according to the present invention includes a copper pattern 120, a liner/barrier layer 130 formed on the lateral and the lower surface of the copper pattern layer 120, a dielectric layer 140 formed on the outer surface of the liner/barrier layer 130, and a capping layer 110 formed on the upper surface of the copper pattern layer 120. The copper pattern layer 120 corresponds to an interconnection of the device, and may be provided in the form of a single damascene or dual damascene structure within the dielectric layer 140, as illustrated in FIGS. 1A to 1C. The liner/barrier layer 130 functions to grow the copper pattern layer 120 on the dielectric layer 140 and to prevent the diffusion of copper atoms, and may be made of a metal such as tantalum (Ta), titanium (Ti), cobalt (Co), ruthenium (Ru), and tungsten (W), or a binary or more compound containing such a metal, or may be provided in the form of two or more layers that are stacked. The liner/barrier layer 130 is preferably formed to cover the lateral and the lower surface, but not the upper surface, of the copper pattern layer 120, but may be formed to cover at least a portion of the copper pattern layer depending on the copper interconnection structure.

The dielectric layer 140 may be an inter-metal dielectric (AVID) layer for insulating the interconnections of the same layer or an inter-layer dielectric (ILD) layer for insulating the interconnections of different layers, and may include silicon nitride (SiNₓ), silicon oxide (SiOₓ) silicon oxynitride (SiOₓN_{y}), silicon carbonitride (SiCₓN_{y}), SiOF, SiOC or other low-k dielectric layers. The dielectric layer 140 may include two or more layers, for example, a passivation layer or an etch-stop layer for forming a single or dual damascene structure.

The capping layer 110 is formed on the exposed upper surface of the copper pattern layer 120 to suppress electromigration on the surface of the copper interconnection, and is a surface-functionalized graphene layer obtained by functionalizing a surface of graphene so that a functional group is formed on at least a portion of the surface thereof. As such, the functional group may include ether (—O), hydroxyl (—OH), epoxide (C—OC), ketone (C═O), carbonyl (>C═O), and carboxyl (COOH), but is not limited to specific functional groups. In the present invention, the surface-functionalized graphene capping layer may be provided in the form of a surface-functionalized graphene monolayer or multilayer, or may include surface-functionalized graphene flakes alone or in stack form.

As illustrated in FIG. 1A, the capping layer 110 may be formed on only the exposed upper surface of the copper pattern layer 120, or may be formed to cover the copper pattern layer 120 and the liner/barrier layer 130, as illustrated in FIG. 1B. Further, when the capping layer 110 has sufficiently superior electrical insulation properties, as illustrated in FIG. 1C, the capping layer may be formed to cover all of the copper pattern layer 120, the liner/barrier layer 130, and the dielectric layer 140. In the present invention, the formation area of the capping layer 110 is not limited, and may vary depending on the copper interconnection structure to which the capping layer 110 is applied. In the present invention, the capping layer 110 is preferably formed so as to fully cover at least the exposed surface of the copper pattern layer 120, but the present invention is not limited thereto.

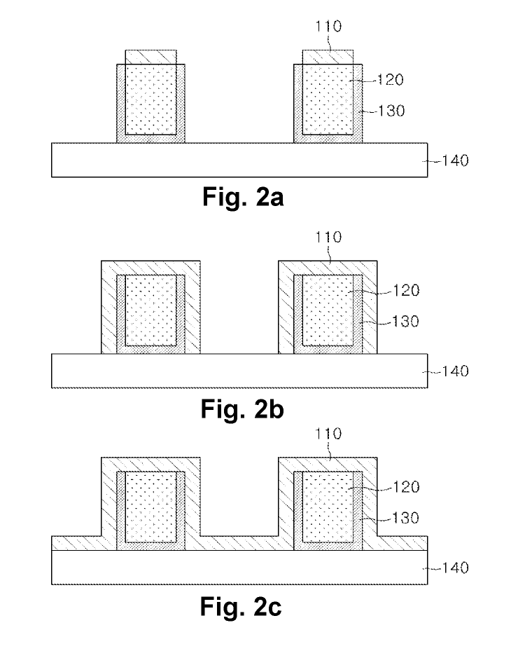

Although the interconnection structures where the inter-metal dielectric (IMD) layer is formed between copper pattern layers 120 are illustrated in FIGS. 1A to 1C, the present invention is not limited to those specific interconnection structures. For example, FIGS. 2A to 2C illustrate interconnection structures having air gaps without the IMD layer between copper pattern layers 120. When the air gap is formed instead of the IMD layer, inter-metal capacitance may decrease, thus minimizing RC delay.

In the interconnection structures having the air gaps as illustrated in FIGS. 2A to 2C, the capping layer 110 may be formed on only the exposed upper surface of the copper pattern layer 120 as illustrated in FIG. 2A, or may be formed to cover the upper surface of the copper pattern layer 120 and the lateral surface of the liner/barrier layer 130 as illustrated in FIG. 2B. Further, when the capping layer 110 has sufficiently superior electrical insulation properties, the capping layer may be formed to cover all of the copper pattern layer 120, the liner/barrier layer 130, and the dielectric layer 140, as illustrated in FIG. 2C. Like the embodiment of FIG. 1, the formation area of the capping layer 110 is not particularly limited.

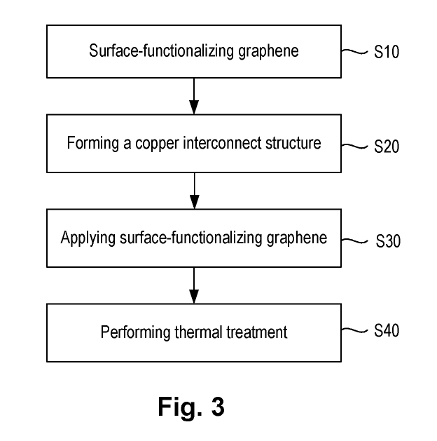

FIG. 3 schematically illustrates a process of fabricating a copper interconnection device according to the present invention. With reference to FIG. 3, the method of fabricating the copper interconnection device according to the present invention includes surface-functionalizing graphene (S10), forming a copper interconnection structure (S20), applying surface-functionalized graphene (S30), and performing thermal treatment (S40). As such, the time-series order of surface-functionalizing the graphene (S10) and forming the copper interconnection structure (S20) is not regarded as important.

Specifically, surface-functionalizing the graphene (S10) is a step of forming a functional group on all or a portion of a surface of graphene. Graphene is a two-dimensional hexagonal carbon material, and graphene for surface functionalization may be graphene oxide, or graphene oxide at least a portion of which is reduced. Also, graphene may be mechanically exfoliated graphene from graphite, chemically exfoliated graphene, or graphene formed by chemical vapor deposition (CVD).

On the surface of the graphene thus provided, a functional group is formed through surface-functionalizing the graphene (S10). Forming the functional group on the surface of the graphene may include diverse processes, such as inducing a chemical reaction on a surface of the graphene using a chemical, adsorbing a polymer on a surface of the graphene, polymerizing a monomer on a surface of the graphene, and performing plasma treatment on a surface of the graphene.

Specifically, inducing a chemical reaction on the surface of the graphene using a chemical is a process for forming a reactive group on a surface of graphene through a chemical reaction between the carbon atoms of the graphene and the chemical, and may include, for example, forming a functional group such as hydroxyl, epoxide, ketone, carbonyl, and carboxyl on the surface of the graphene using a strong oxidant. As such, Hummer's Method or Modified Hummer's Method may be employed.

Adsorbing a polymer on the surface of the graphene is a process for adsorbing a polymer on a surface of graphene or surface-functionalized graphene. Thereby, since the functional group present in the corresponding polymer may be utilized for chemical interaction with copper atoms, it is easy to form a desired functional group, and also the functional group may be formed at high density on the surface of the graphene.

Polymerizing a monomer on the surface of the graphene is a process for inducing polymerization of a monomer on a surface of graphene so as to grow into a polymer thereon, instead of directly adsorbing a polymer on the surface of the graphene. Even when such a process is performed, the functional group may be formed at high density on the surface of the graphene, as in the process for adsorbing the polymer.

Performing plasma treatment on the surface of the graphene to form a functional group is a process for inducing bonding of carbon atoms of graphene with oxygen or hydrogen through oxygen or hydrogen plasma treatment. For example, when the surface of the graphene is exposed to oxygen plasma, sp2 bonds of the graphene are broken, and an oxygen-containing functional group is formed.

In addition thereto, a variety of processes for forming the functional group on the surface of the graphene may be utilized, and thus surface-functionalizing the graphene (S10) is not limited to specific processes. Also, a single functional group or a combination of two or more functional groups may be formed on the surface of the graphene.

Next, forming the copper interconnection structure (S20) is a step of forming a copper interconnection structure on which the surface-functionalized graphene capping layer is to be applied, where the copper interconnection structure is configured such that at least a portion of the copper pattern layer 120 is exposed. As such, the copper interconnection structure is not limited to a specific structure, and may include, for example, a single damascene structure or a dual damascene structure, and may further include the liner/barrier layer 130 and the dielectric layer 140. As such, the dielectric layer 140 or the air gap may be formed between copper pattern layers 120.

Next, applying the surface-functionalized graphene (S30) is a step of applying the surface-functionalized graphene on the exposed surface of the copper pattern layer 120 to form a capping layer. As such, the coating process is not particularly limited, and may include spin coating, spray coating or dip coating using a coating solution including the surface-functionalized graphene obtained in S10, and transferring a surface-functionalized graphene layer.

Meanwhile, in order to form the surface-functionalized graphene capping layer 110 on only a portion of the interconnection structure as shown in FIG. 1A or 1B, any graphene patterning process may be employed. For example, the surface-functionalized graphene is applied on the entire copper interconnection structure, and then the surface-functionalized graphene alone may be removed from the upper surface of the dielectric layer 140. As such, removing the surface-functionalized graphene may include oxygen plasma treatment, hydrogen plasma treatment, or argon plasma treatment. In this procedure, the thickness of the capping layer 110 applied on the copper pattern layer 120 may or may not be decreased.

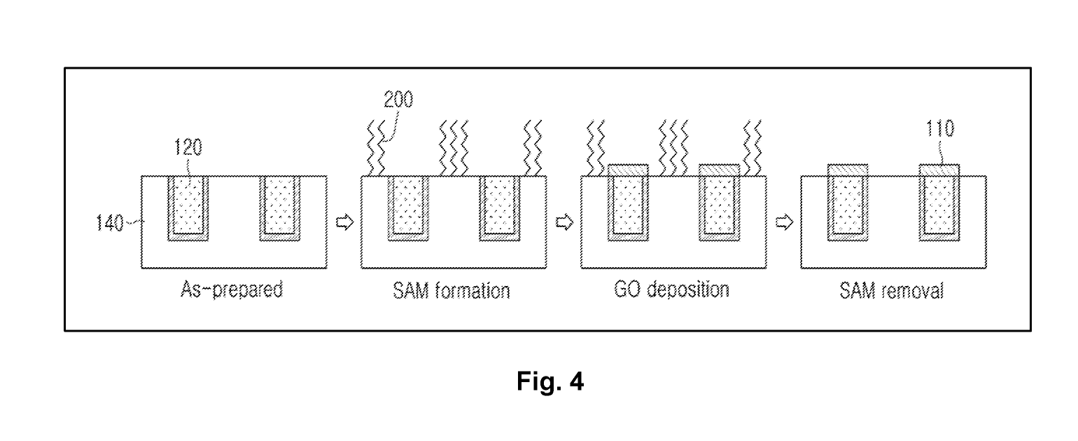

Alternatively, the surface-functionalized graphene capping layer may be selectively formed on only a portion of the interconnection structure. FIG. 4 illustrates selective formation of the surface-functionalized graphene capping layer on the portion of the interconnection structure other than the dielectric layer 140. As illustrated in FIG. 4, a self-assembly monolayer (SAM) material 200 is first applied on the copper interconnection structure obtained in S20. The SAM material 200 may include alkyltrichlorosilane or octadecyltrichlorosilane, and such a material may be selectively formed on only the upper surface of the dielectric layer 140. Thereafter, the surface-functionalized graphene is applied thereon, and the SAM material 200 is then removed, and thereby the surface-functionalized graphene capping layer 110 may be selectively formed on only the portion of the interconnection structure other than the dielectric layer 140. As such, removing the SAM material 200 may include oxygen plasma treatment, hydrogen plasma treatment, or argon plasma treatment.

After applying the surface-functionalized graphene (S30), thermal treatment (S40) may be implemented. Thermal treatment (S40) is a step of enhancing the chemical interaction between the functional groups of the capping layer 110 and the copper atoms of the copper pattern layer 120. As it is difficult to move the copper atoms because of such a chemical interaction, electromigration is effectively suppressed on the surface of the copper interconnection. In some cases, thermal treatment (S40) may be omitted.

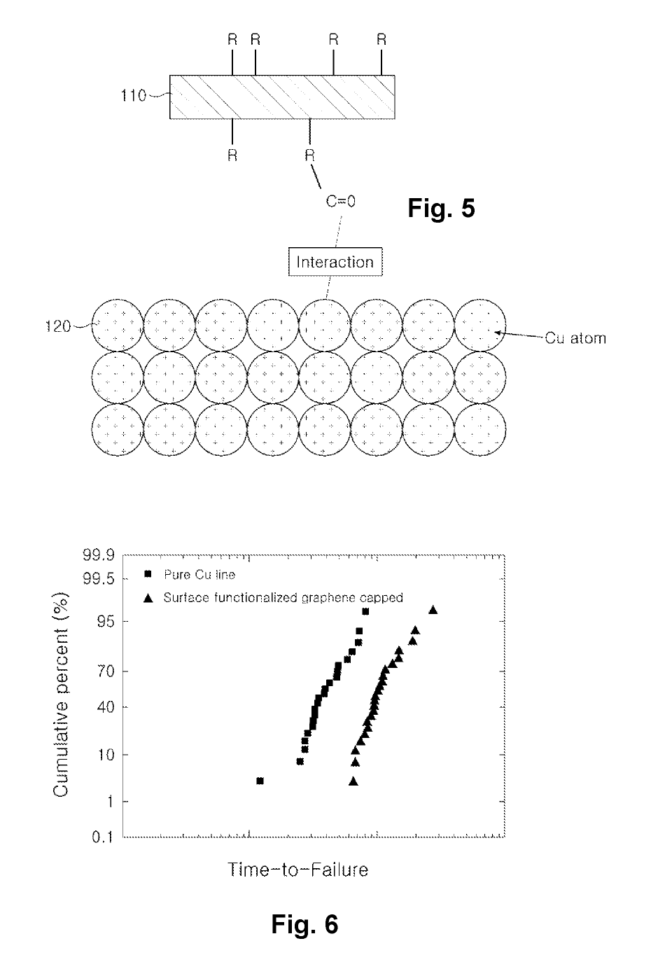

FIG. 5 illustrates the chemical interaction between the functional groups of the capping layer 110 and the copper atoms of the copper pattern layer 120. FIG. 5 exemplarily illustrates graphene functionalization so as to possess the carbonyl functional group. Specifically, the chemical interaction may occur between the carbonyl functional group of the surface of the capping layer 110 and the copper atom, and thus movement of the copper atom becomes difficult, whereby electromigration is suppressed on the surface of the copper interconnection. As such, the chemical interaction may cause charge transfer between the functional group and the surface copper atom to thus form a bond between the copper atom and the functional group, ultimately decreasing the likelihood that the copper atom will be moved out of the original position thereof.

When the graphene having a functional group on the surface thereof is used as the capping layer in this way, it may be advantageously applied to a fine copper interconnection because electromigration of the copper interconnection may be suppressed even by the capping layer as thin as ones of nm or less. Specifically, graphene is theoretically composed exclusively of hexagonal carbon atoms and thus has very low chemical reactivity and is stable, but in the present invention, the surface of the graphene is introduced with the functional group and thus functionalized, so that thin film properties of monolayer graphene are maintained and the effects thereof on copper atoms may be enhanced, thereby enabling such graphene to function as the capping layer. When graphene having no functional group is used as the capping layer, it is possible to form a thin capping layer but only an effect of suppressing electromigration based on a current dispersion effect may be expected, making it difficult to ensure the effect of suppressing electromigration based on chemical interactions, as in the present invention.

The effects of the present invention are described via the following test example.

### Test Example

A surface-functionalized graphene capping layer was applied on a copper interconnection structure, after which electromigration was measured. Graphene was surface-functionalized in such a manner that a polymer was adsorbed on the surface of the graphene. Specifically, polyvinylpyrrolidone (PVP) was mixed with distilled water and stirred, and the resulting polymer solution was mixed with a graphene aqueous solution, thus preparing a coating solution for a capping layer. In this procedure, PVP was adsorbed on the surface of the graphene, and thereby a functional group was formed on the surface of the graphene. The coating solution thus prepared was applied through spin coating on the copper interconnection structure, thus forming a capping layer having a thickness of 3 nm or less, followed by thermal treatment at 150° C. for 3 min, thereby maximizing the chemical interaction between copper atoms and functional groups.

As the copper interconnection for measurement of electrical properties, a single-damascene copper interconnection having a width of 110 nm, a thickness of 160 nm, and a length of 975 μm was used.

FIG. 6 illustrates the results of measurement of time to failure of the copper interconnection depending on the presence or absence of the surface-functionalized graphene capping layer. Electromigration is a phenomenon where resistance of the interconnection is increased due to the migration of copper atoms by current flowing in the copper interconnection. The time to failure of the copper interconnection was set to a point of time at which resistance was increased to a specific ratio or more relative to the initial resistance under the condition that certain current was applied. As illustrated in FIG. 6, the surface-functionalized graphene was provided as the capping layer, thereby significantly increasing the average time to failure of the copper interconnection.

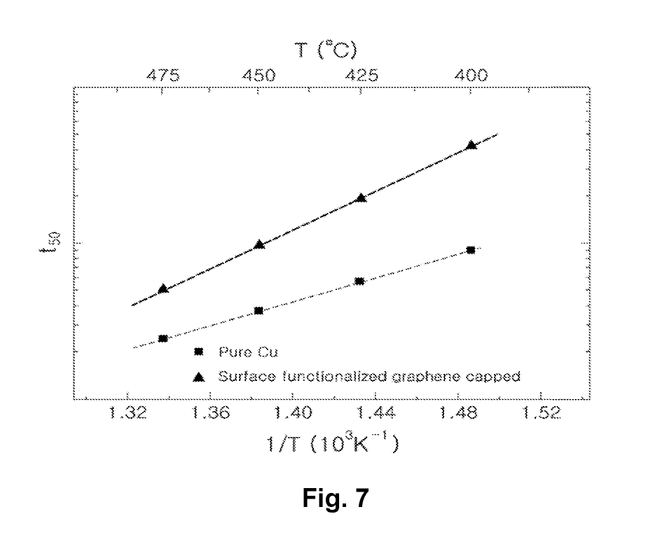

FIG. 7 illustrates the results of measurement of time to failure of the copper interconnection under various temperature conditions depending on the presence or absence of the surface-functionalized graphene capping layer, from which the activation energy for electromigration can be determined. As shown in the graph of FIG. 7, changes in time to failure of the sample having the surface-functionalized graphene capping layer depending on the temperature were drastic, which means that the activation energy for electromigration is greater in the presence of the surface-functionalized graphene capping layer.

Although the preferred embodiments of the present invention have been disclosed for illustrative purposes with reference to the drawings, those skilled in the art will appreciate that various modifications are possible within the scope of the present invention. For example, the copper interconnection device according to the present invention may include all devices including copper interconnections, and is not limited to a copper interconnection device having any specific structure. For instance, the copper interconnection device may include a copper interconnection monolayer or multilayer. Embodiments of the present invention describe some of the methods of fabricating the copper interconnection device, and it is to be understood that additional steps be carried out depending on the copper interconnection structure. For example, although the steps up to thermal treatment (S40) are described in FIG. 4, a dielectric layer for forming a multilayer structure or a dielectric layer for passivation may be deposited on the capping layer in the copper interconnection structure, and a copper interconnection layer may be further formed thereon, as necessary.

In the present invention, the interaction between the surface-functionalized graphene capping layer and the copper pattern layer is not necessarily limited to the chemical interaction, but may be any interaction based on physical adsorption. The present invention is characterized in that graphene surface-functionalized so as to possess the functional group is used as the capping layer, but not identifying the mechanism for suppressing electromigration. Therefore, the scope of the present invention has to be defined by the range described in the claims and their equivalents.

What is claimed is:

1. A copper interconnection device, comprising:
a copper pattern layer;
a liner/barrier layer formed on at least a portion of a lateral surface and a lower surface of the copper pattern layer;
a dielectric layer formed so as to come into contact with at least a portion of an outer surface of the liner/barrier layer; and
a capping layer formed on an exposed surface of the copper pattern layer,
wherein the capping layer is graphene having a functional group on a surface thereof.

2. The copper interconnect device of claim 1, wherein the capping layer is formed on the liner/barrier layer.

3. The copper interconnect device of claim 1, wherein the capping layer is formed on the dielectric layer.

4. The copper interconnect device of claim 1, wherein the capping layer is a graphene monolayer or multilayer having a functional group on a surface thereof, or is configured such that surface-functionalized graphene flakes are stacked.

5. The copper interconnect device of claim 1, wherein the functional group is a single functional group or a combination of two or more functional groups.

6. A method of fabricating a copper interconnection device, comprising:
surface-functionalizing graphene;
forming a copper interconnection structure;
applying the surface-functionalized graphene on the copper interconnection structure; and
performing thermal treatment,
wherein surface-functionalizing the graphene is forming a functional group on a surface of the graphene.

7. The method of claim 6, wherein surface-functionalizing the graphene comprises forming a functional group on the surface of the graphene using at least one of inducing a chemical reaction on a surface of the graphene using a chemical, adsorbing a polymer on a surface of the graphene, and polymerizing a monomer on a surface of the graphene, and performing plasma treatment on a surface of the graphene.

8. The method of claim 6, wherein applying the surface-functionalized graphene comprises at least one of spin coating, spray coating or dip coating using a coating solution including the surface-functionalized graphene, and transferring a surface-functionalized graphene layer.

9. The method of claim 6, wherein applying the surface-functionalized graphene comprises selectively forming graphene on a portion of the copper interconnection structure.

10. The method of claim 9, wherein selectively forming the graphene on the portion of the copper interconnection structure comprises:
applying a self-assembly monolayer material on the copper interconnection structure;
applying the surface-functionalized graphene; and
removing the self-assembly monolayer material.
